(19) United States
(12) Patent Application Publication
(10) Pub. No.: US 2026/0282877 A1
(43) Pub. Date: Sep. 17, 2026

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 19/646,746

(22) Filed: Apr. 14, 2026

Related U.S. Application Data
(63) Continuation of application No. PCT/JP2023/037786, filed on Oct. 19, 2023.

(51) Int. Cl. H10W 20/41; H10D 84/85; H10W 20/20; H10W 20/43; H10D 89/10

(52) U.S. Cl. CPC H10W 20/427; H10D 84/851; H10W 20/2134; H10W 20/43; H10W 20/435; H10D 89/10

(57) ABSTRACT

A semiconductor device includes a substrate; a first power supply line extending in a first direction in plan view on a first surface of the substrate; a first semiconductor layer and a second semiconductor layer provided on a second surface of the substrate opposite to the first surface and arranged side by side in the first direction overlapping the first power supply line in plan view; a first through via formed in the substrate and connecting the first power supply line and the second semiconductor layer; a third semiconductor layer formed above the first semiconductor layer; a fourth semiconductor layer formed above the second semiconductor layer; a first gate formed between the first semiconductor layer and the second semiconductor layer and between the third semiconductor layer and the fourth semiconductor layer; and a first transistor having the first semiconductor layer, the second semiconductor layer, and the first gate.

### CROSS-REFERENCE TO RELATED APPLICATION

The present application is a continuation application of International Application No. PCT/JP2023/037786 filed on October 19, 2023, the contents of which are incorporated herein by reference in their entirety.

### FIELD

The present disclosure relates to a semiconductor device.

### BACKGROUND

There is a technology referred to as CFET (Complementary Field Effect Transistor) which configures a CMOS (Complementary Metal-Oxide-Semiconductor) by stacking transistors in a direction perpendicular to a substrate. The CFET greatly reduces the area occupied by a CMOS basic cell and miniaturizes a semiconductor device. In a technology referred to as BS-PDN (Backside Power Delivery Network) which supplies a power supply voltage to a circuit on the front surface of a semiconductor substrate from the back surface of the substrate, in some cases, a structure in which a Through Silicon Via (TSV) penetrates the substrate and is directly connected to the source/drain of a transistor is used. There is a technology referred to as a power wall in which a conductive wall spans the height of upper and lower transistors of a CFET to supply power to each transistor. There is a technology in which a power switch circuit for controlling on/off of supply of a power supply voltage is provided in a circuit such as a standard cell.

### Related Art Documents

### Patent Documents

Patent Document 1: U.S. Patent Application Publication No. 2022/0068921

Patent Document 2: U.S. Patent Application Publication No. 2023/0178435

Patent Document 3: U.S. Patent Application Publication No. 2023/0067311

Patent Document 4: U.S. Patent Application Publication No. 2022/0123023

Patent Document 5: U.S. Patent Application Publication No. 2022/0181258

Patent Document 6: WO 2020/065916

Patent Document 7: WO 2020/066797

Patent Document 8: WO 2020/217396

Patent Document 9: WO 2020/217400

Patent Document 10: U.S. Patent Application Publication No. 2021/0366902

Patent Document 11: U.S. Patent Application Publication No. 2022/0102479

Patent Document 12: U.S. Patent Application Publication No. 2021/0210600

Patent Document 13: U.S. Patent No. 10950546

Patent Document 14: U.S. Patent No. 11004789

### SUMMARY

In one embodiment, a semiconductor device includes a substrate; a first power supply line extending in a first direction in plan view on a first surface of the substrate; a first semiconductor layer and a second semiconductor layer provided on a second surface of the substrate opposite to the first surface and arranged side by side in the first direction overlapping the first power supply line in plan view; a first through via formed in the substrate and connecting the first power supply line and the second semiconductor layer; a third semiconductor layer formed above the first semiconductor layer; a fourth semiconductor layer formed above the second semiconductor layer; a first gate formed between the first semiconductor layer and the second semiconductor layer and between the third semiconductor layer and the fourth semiconductor layer; a first transistor having the first semiconductor layer, the second semiconductor layer, and the first gate; a first conductive wall and a second conductive wall shifted in a second direction different from the first direction from the first power supply line in plan view, and extending in the first direction on the second surface; and a first wiring connecting the first conductive wall and the first semiconductor layer.

The object and advantages of the invention will be implemented and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a schematic diagram illustrating an outline of a layout of a semiconductor device of an embodiment;

FIG. 2 is a schematic cross-sectional view illustrating an example of a wiring structure of a circuit region of a semiconductor device;

FIG. 3 is a schematic diagram illustrating an outline of a semiconductor device of an embodiment;

FIG. 4 is a plan view of a backside wiring layer (BSM) of a semiconductor device of an embodiment;

FIG. 5 is a plan view of a bottom layer of a semiconductor device of an embodiment;

FIG. 6 is a plan view of a top layer of a semiconductor device of an embodiment;

FIG. 7 is a cross-sectional view taken along Y1-Y1’ of FIGS. 4 to 6;

FIG. 8 is a cross-sectional view taken along Y2-Y2’ of FIGS. 4 to 6;

FIG. 9 is a cross-sectional view taken along X1-X1’of FIGS. 4 to 6;

FIG. 10 is a plan view of the bottom layer of a first modified example;

FIG. 11 is a plan view of the bottom layer of a second modified example; and

FIG. 12 is a plan view of the bottom layer of a third modified example.

### DESCRIPTION OF EMBODIMENTS

How a power switch circuit is to be laid out in a circuit for supplying power to a CFET by a power wall has not been studied in detail. Accordingly, it is desired to provide a semiconductor device having a power switch circuit efficiently laid out in a configuration for supplying power by a power wall.

In an embodiment, a power switch circuit having an efficient layout in a semiconductor device in which a power wall is used as a part of a power supply line for supplying a power voltage to a CFET, is provided. In particular, an efficient arrangement relationship between a switch transistor for switching supply of a power voltage to a standard cell, and the power wall, is provided. Hereinafter, a specific configuration of the semiconductor device of the embodiment will be described with reference to the drawings. The embodiments described below are examples for implementing the technical concept of the present disclosure and are not intended to limit the contents of the disclosure. The sizes and positional relationships of the components illustrated in the drawings may be exaggerated to facilitate understanding of the invention. In some cases, the same components or functions are given the same names or reference numerals and redundant descriptions are omitted.

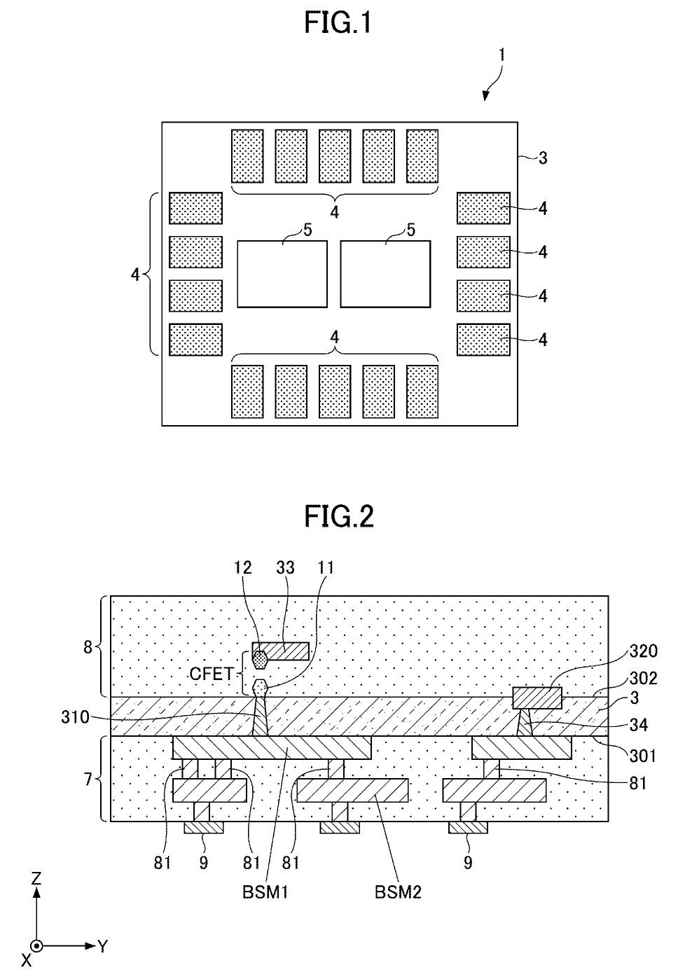

FIG. 1 is a schematic diagram illustrating an outline of a layout of a semiconductor device 1 according to an embodiment. The semiconductor device 1 has one or more circuit regions 5 provided on a substrate 3 and a plurality of input/output (I/O) cell regions 4 arranged on the substrate 3. The circuit region 5 may have a standard cell including a plurality of logic circuits, or may have other circuits such as a gate array, SRAM (Static Random Access Memory), and analog circuits.

FIG. 2 is a schematic cross-sectional view illustrating an example of a wiring structure of the circuit region 5 of the semiconductor device 1. In the coordinate system of FIG. 2, the plane parallel to the substrate 3 is the XY plane, and the direction perpendicular to the substrate 3, that is, the lamination direction is the Z direction. The semiconductor device 1 has a first wiring layer 7 on the back surface 301 side of the substrate 3 and a second wiring layer 8 on the front surface 302 side of the substrate. The semiconductor device 1 supplies a power supply voltage from the back surface 301 of the substrate 3 to a circuit on the front surface 302 side of the substrate 3. Here, the back surface 301 of the substrate 3 is referred to as a “first surface” and the front surface 302 is referred to as a “second surface”. A CFET having a first transistor 11 and a second transistor 12 in a direction perpendicular to the substrate 3, is arranged on the front surface 302 side of the substrate 3. The first transistor 11 on the bottom side may be referred to as a “bottom transistor” and the second transistor on the upper side may be referred to as a “top transistor”. In this figure, the source and drain (hereinafter referred to as “source/drain” as appropriate) of the first transistor 11 and the second transistor 12 are extended in the X direction perpendicular to the plane of the drawing.

In the first wiring layer 7, a power supply line for supplying an operating voltage of the circuit and a power supply line for supplying a reference voltage lower than the operating voltage are formed. In the example illustrated in FIG. 2, a first layer wiring (BSM1) on the back surface 301 of the substrate 3 and a second layer wiring (BSM2) on the back surface 301 are provided. The first layer wiring BSM1 and the second layer wiring BSM2 are connected by a via plug 81. A pad 9 serving as an external connection terminal is formed on the lowermost surface of the first wiring layer 7. The first wiring layer 7 may be a wiring layer directly formed on the back surface 301 of the substrate 3, or may be a wiring layer formed on another chip (i.e., a substrate) bonded to the back surface 301 of the substrate 3.

The wirings BSM1 and BSM2 of the first wiring layer 7 are connected to the semiconductor layer of the first transistor 11 of the CFET by a through via 310 penetrating the substrate 3. The wirings BSM1 and BSM2 of the first wiring layer 7 may be connected to the semiconductor layer of the second transistor 12 of the CFET by a through via (not illustrated) provided in the substrate 3 and a wiring 33 formed on the second wiring layer 8. An embedded wiring 320 connected to the through via 34 may be provided on the front surface 302 side of the substrate 3. The connection between the wirings on the back surface 301 of the substrate 3 and the first transistor 11 on the bottom side of the CFET may be implemented by a conductive wall (also referred to as a “power wall”) extending vertically from the back surface 301 to the front surface 302 side of the substrate 3 and the wiring connected to the conductive wall, as described below.

### Outline of a semiconductor device of an embodiment

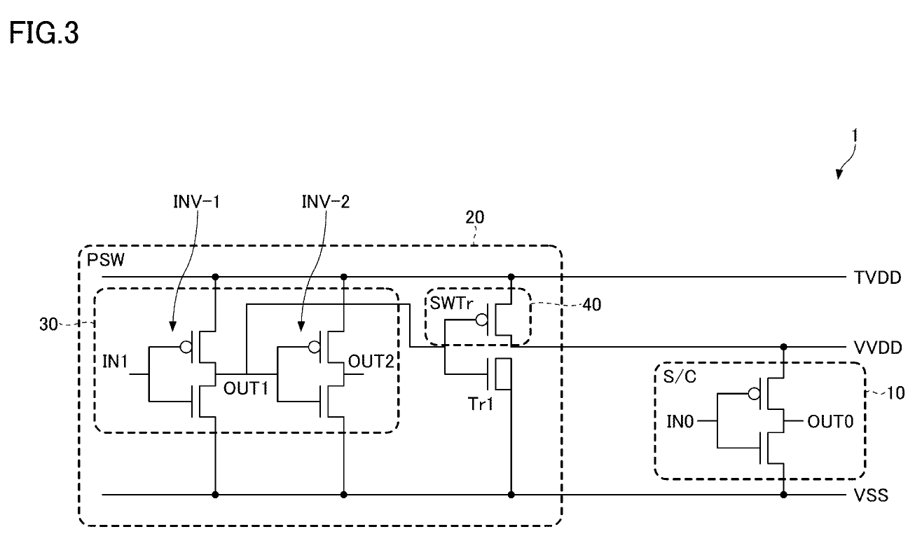

FIG. 3 is a diagram illustrating an outline of a semiconductor device 1. The semiconductor device 1 includes a standard cell 10 and a power switch circuit (denoted as “PSW” in the figure) 20 for switching on and off the supply of a power supply to the standard cell 10. The standard cell 10 has a minimum unit circuit for performing a basic operation by various logic circuits such as NAND, NOR, AOI (AND-OR INV), and flip-flop. In the example of FIG. 3, the standard cell 10 is an inverter, but the present invention is not limited to this example, and other logic circuits may be used.

The power switch circuit 20 includes a switch transistor (denoted as “SWTr” in the figure) 40 for turning on and off the supply of a power supply to the standard cell 10, and a control circuit 30 for controlling the switch transistor 40. In a configuration in which the power switch circuit 20 turns on and off the supply of a power supply to a circuit such as the standard cell 10, three types of power supply lines are used: true VDD (TVDD), virtual VDD (VVDD), and VSS. TVDD and VVDD supply an operating voltage of the circuit. VSS supplies a reference voltage lower than VDD. As will be described below, the power supply lines TVDD and VSS may have a conductive wall (or power wall) perpendicular to the substrate.

The standard cell 10 is electrically connected between VSS and VVDD. The power switch circuit 20 is electrically connected between VSS and TVDD. If the power supply voltage is always supplied to the standard cell 10 even when the standard cell 10 is not in use, leakage may occur and power consumption may increase. In order to suppress this, the standard cell 10 is connected to a virtual power supply line VVDD, and the power supply voltage is supplied from the TVDD to the VVDD when necessary. The power supply from the TVDD to the VVDD to which the standard cell is connected is executed by the switch transistor 40 based on an instruction from the control circuit 30. In this example, the switch transistor 40 is composed of a PMOS transistor, and its source is connected to the TVDD and its drain is connected to the VVDD.

The control circuit 30 is provided between TVDD and VSS, and the output of the inverter INV-1 included in the control circuit 30 is input to the gate of the switch transistor 40. The switch transistor 40 turns on and off the power supply voltage supply from TVDD to VVDD based on a control signal from the control circuit 30. In the configuration example of FIG. 3, the switch transistor 40 is controlled by a signal “OUT 1” from a node between the two inverters INV-1 and INV-2, but the control circuit 30 is not limited to this example, and may take any configuration for controlling the switching operation of the power supply voltage supply of the switch transistor 40.

A transistor Tr1 similar to NMOS is connected to the gate of a switch transistor 40 formed of PMOS. The switch transistor 40 and the transistor Tr1 are formed as CFETs stacked in a direction perpendicular to the substrate and connected to a common gate. In FIG. 3, portions corresponding to the source and drain of the transistor Tr1 are connected to the VSS, but they may be floating. The transistor Tr1 may be a dummy top transistor formed in a common process with the CFETs of the standard cell 10 and the control circuit 30. Further, instead of forming a dummy top transistor, formation of some top transistors may be omitted.

When switching on/off the power supply to the standard cell 10 in a circuit using three types of power supply lines, i.e., TVDD, VVDD, and VSS, it is important to design a specific wiring of the power switch circuit 20. In particular, an efficient layout is required when TVDD and VSS, which supply power supply voltages, are formed as conductive walls.

### Concrete Configuration of Semiconductor Device

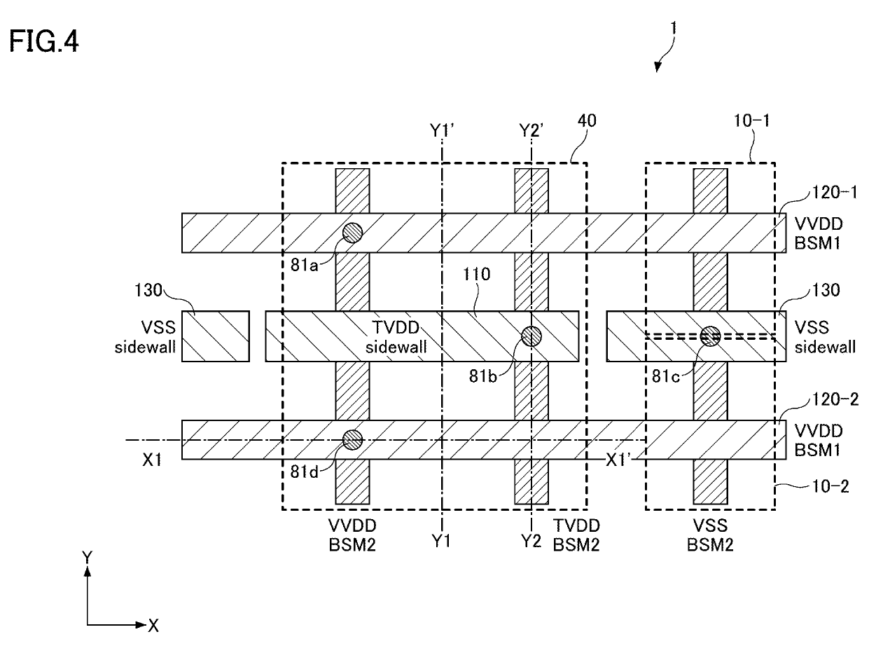

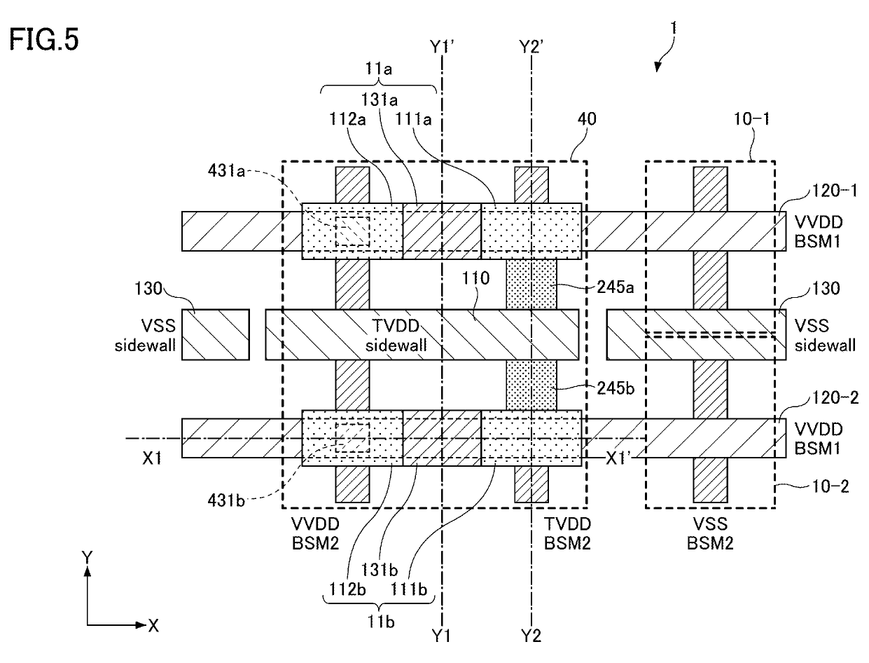

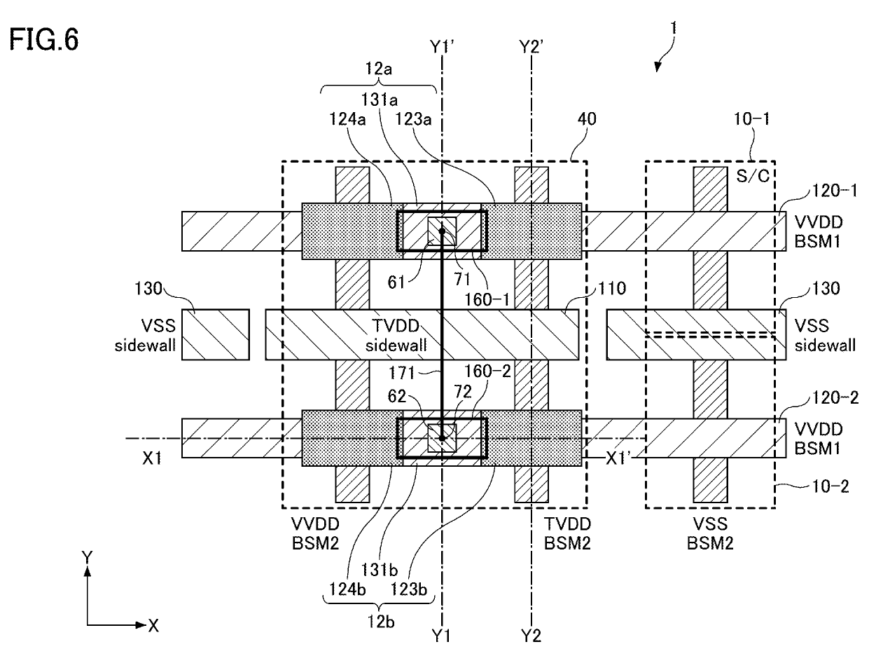

FIG. 4 is a plan view of a back side metal (BSM), FIG. 5 is a plan view of a bottom layer, and FIG. 6 is a plan view of a top layer of the semiconductor device 1 according to the embodiment. The BSM is a wiring layer (see FIG. 2) included in a first wiring layer 7 on the back surface 301 side of the substrate 3, the bottom layer is a layer including a first transistor 11 of a CFET provided on the front surface 302 side (front side) of the substrate 3, and the top layer is a layer including a second transistor 12 of a CFET.

### Plan Arrangement Example of BSM

In FIG. 4, a VVDD 120-1, which is a first power supply line, is arranged in a first direction (for example, an X direction) in the region of the switch transistor 40 on the back surface first layer (BSM1). A TVDD sidewall 110, which is a first conductive wall, extends in the X direction from VVDD 120-1 while being shifted in a second direction different from the first direction. In the example of FIG. 4, the TVDD sidewall 110 is shifted in the −Y direction from VVDD 120-1. In the coordinate axes of the embodiment, a direction indicated by an arrow indicating an X direction or a Y direction is referred to as a plus (+) direction, and a direction opposite to the plus direction is referred to as a minus (-) direction. The TVDD sidewall 110 supplies an operating voltage of the circuit. A VVDD 120-2 may be provided on the opposite side of the VVDD 120-1 with the TVDD sidewall 110 interposed therebetween.

Regions of standard cells 10-1 and 10-2 are provided adjacent to the region of the switch transistor 40 in the X direction. The VVDD 120-1 and 120-2 extend into the regions of standard cells 10-1 and 10-2, respectively. A VSS sidewall 130 extending in the X direction is provided between the VVDD 120-1 and 120-2 in the regions of standard cells 10-1 and 10-2. The VSS sidewall 130 is a second conductive wall and supplies a reference voltage lower than the operating voltage. The TVDD sidewall 110 and the VSS sidewall 130 are adjacent in the X direction. The TVDD sidewall 110 may be arranged between a plurality of VSS sidewalls 130 in the X direction in order to arrange another circuit of the power switch circuit 20, such as an inverter of the control circuit 30. As illustrated in FIG. 4, the TVDD sidewall 110 may be arranged at a position where the VSS sidewall 130 is cut off.

A TVDD BSM2, a VVDD BSM2, and a VSS BSM2 are formed on the back surface second layer (BSM2) of the substrate 3 in the Y direction crossing the wiring of the back surface first layer. The TVDD sidewall 110 is connected to the TVDD BSM2 of the second layer by a via plug 81b. The VVDD 120-1 and 120-2 are connected to the VVDD BSM2 of the second layer by via plugs 81a and 81d, respectively. The VSS sidewall 130 is connected to the VSS BSM2 of the second layer by a via plug 81c.

When the power supply voltage from the TVDD sidewall 110 to the VVDD 120-1 and 120-2 is turned on by the switch transistor 40, the power supply voltage is supplied to the standard cells 10-1 and 10-2, and the standard cells 10-1 and 10-2 operate.

### Example of Planar Arrangement of Bottom Layer

FIG. 5 is a plan view of the bottom layer of the front surface 302 of the substrate 3. In this example, the TVDD sidewall 110 and the VSS sidewall 130 extending in the X direction are conductive walls extending through the substrate 3 to the height of the CFET on the front surface 302 side. One or both of the TVDD sidewall 110 and the VSS sidewall 130 may be conductive walls rising from the front surface of the substrate 3 to the height of the second transistor 12 of the CFET. In this case, a through via formed in the substrate 3 may be connected to the TVDD sidewall 110 and/or the VSS sidewall 130, and power supply voltages corresponding to the TVDD sidewall 110 and the VSS sidewall 130 may be supplied from the back surface 301 of the substrate 3 via the through via. The TVDD sidewall 110 and the VSS sidewall 130 may be conductive walls rising to a position higher than the second transistor 12 of the CFET (see FIG. 2). Further, in place of one or both of the TVDD sidewall 110 and the VSS sidewall 130, a power supply line for supplying a power supply voltage to the back surface 301 of the substrate 3 may be arranged.

In the switch transistor 40, a first semiconductor layer 111a and a second semiconductor layer 112a are provided at positions overlapping the VVDD 120-1 on the back surface in plan view with an interval in the X direction. The first semiconductor layer 111a is connected to the TVDD sidewall 110 by a wiring 245a projecting in the -Y direction. The second semiconductor layer 112a is connected to the VVDD 120-1 on the back surface 301 of the substrate 3 by a through via 431a penetrating the substrate 3. A gate 131a is arranged between the first semiconductor layer 111a and the second semiconductor layer 112a to form a first transistor 11a.

Another first transistor 11b is arranged on the opposite side of the first transistor 11a with the TVDD sidewall 110 interposed therebetween. A first semiconductor layer 111b and a second semiconductor layer 112b are provided at a position overlapping the VVDD 120-2 on the back surface in plan view with an interval in the X direction. The first semiconductor layer 111b is connected to the TVDD sidewall 110 by a wiring 245b protruding in the +Y direction. The second semiconductor layer 112b is connected to the VVDD 120-2 on the back surface 301 of the substrate 3 by a through via 431b penetrating the substrate 3. A gate 131b is arranged between the first semiconductor layer 111b and the second semiconductor layer 112b to form a first transistor 11b.

The first transistors 11a and 11b are connected in parallel as described below with reference to FIG. 6. An impurity of a first conductivity type (e.g., p-type) is added to the first semiconductor layers 111a and 111b and the second semiconductor layers 112a and 112b. The first transistors 11a and 11b functioning as the switch transistor 40 are turned on and off in accordance with signals input to the gates 131a and 131b. The entire first transistors 11a and 11b (optionally collectively referred to as “first transistor 11”) connected in parallel may be used as the switch transistor 40. By connecting a plurality of first transistors 11 in parallel, the size of the transistors can be increased and a large current can flow.

In the regions of the standard cells 10-1 and 10-2, semiconductor layers serving as the source and drain of the bottom transistor can be formed at positions overlapping the VVDD 120-1 and 120-2 in plan view. Because any arrangement of the CFETs in the standard cells 10-1 and 10-2 can be adopted, the arrangement of the CFETs inside the standard cells 10-1 and 10-2 is not particularly illustrated in this embodiment.

According to the arrangement illustrated in FIG. 5, a plurality of first transistors 11 are provided on both sides in the Y direction of the TVDD sidewall 110 extending in the X direction. The first semiconductor layers 111b and 111a can be connected to the TVDD sidewall 110 by a wiring 245b projecting in the +Y direction and wirings 245a projecting in the −Y direction, respectively.

### Top Layer Plan Configuration Example

FIG. 6 is a plan view of the top layer of the front surface 302 of the substrate 3. In the switch transistor 40, a third semiconductor layer 123a is provided above the first semiconductor layer 111a, and a fourth semiconductor layer 124a is provided above the second semiconductor layer 112a. A gate 131a used in common with the first transistor 11a is provided between the third semiconductor layer 123a and the fourth semiconductor layer 124a to form the second transistor 12a.

Similarly, a third semiconductor layer 123b is provided above the first semiconductor layer 111b, and a fourth semiconductor layer 124b is provided above the second semiconductor layer 112b. A gate 131b used in common with the first transistor 11b is provided between the third semiconductor layer 123b and the fourth semiconductor layer 124b to form the second transistor 12b.

A second conductivity type (e.g., n-type) impurity different from the first conductivity type is added to the third semiconductor layers 123a and 123b and the fourth semiconductor layers 124a and 124b. Although the third semiconductor layers 123a and 123b and the fourth semiconductor layers 124a and 124b are floating in this example, they may be electrically connected to the VSS sidewall 130 via, for example, wiring or via plugs not illustrated. In the present invention, portions that do not operate as transistors, such as the second transistors 12a and 12b, are referred to as transistors in some cases.

A gate 131a commonly used for the first transistor 11a and the second transistor 12a is electrically connected to the upper layer wiring 160-1 by a via plug 61, and a control signal output from the control circuit 30 is applied to the gate 131a via the upper layer wiring 160-1. A gate 131b commonly used for the first transistor 11b and the second transistor 12b is electrically connected to the upper layer wiring 160-2 by a via plug 62, and a control signal output from the control circuit 30 is applied to the gate 131b via the upper layer wiring 160-2.

The upper layer wiring 160-1 is connected to the via plug 71, and the upper layer wiring 160-2 is connected to the via plug 72. The via plugs 71 and 72 are further connected to the upper layer wiring 171, and the gates 131a and 131b are electrically connected. Thus, the first transistors 11a and 11b are connected in parallel. With this configuration, a plurality of the first transistors 11a and 11b are connected in parallel in the vicinity of the TVDD sidewall 110, and the scale of the switch transistor 40 can be increased.

### Cross-sectional Structure

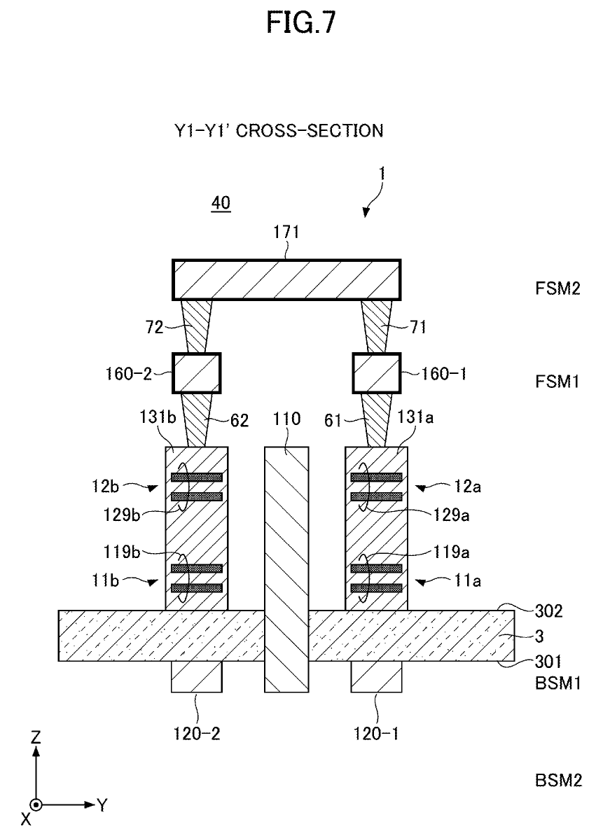

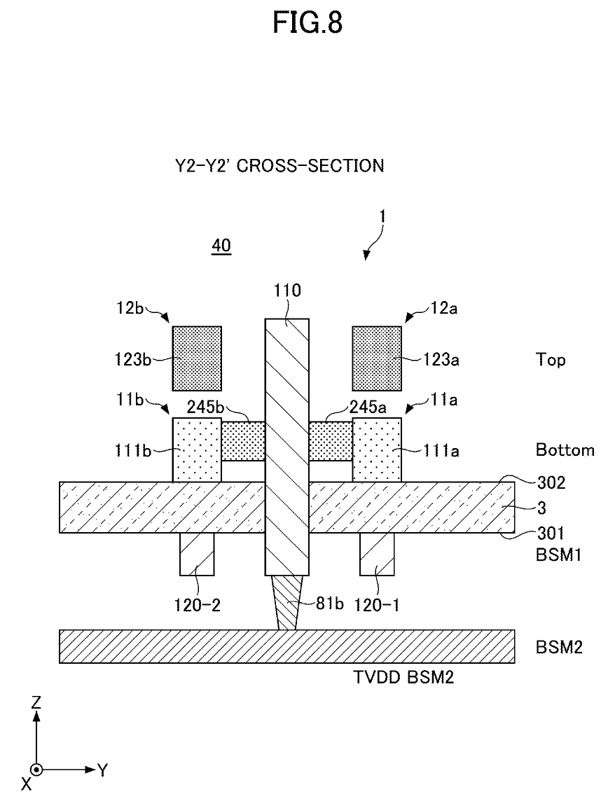

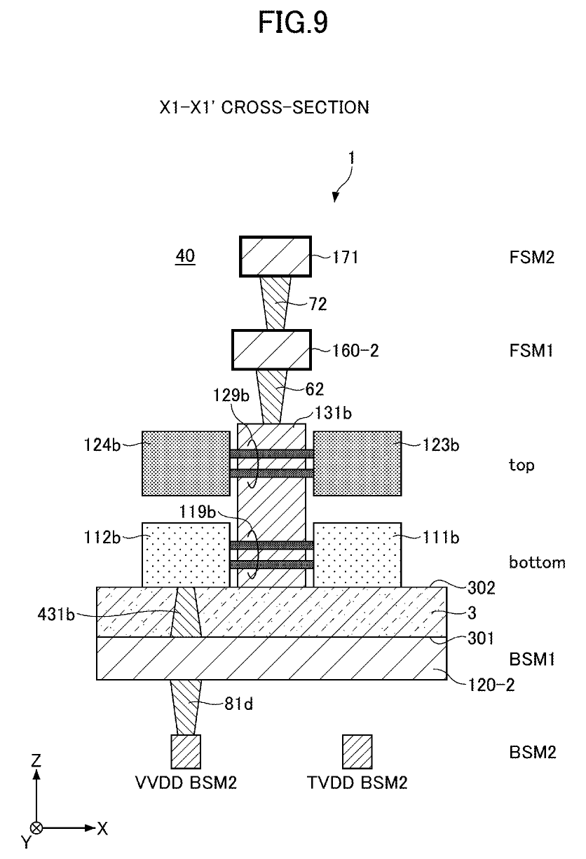

FIG. 7 is a cross-sectional view of FIGS. 4 to 6 taken along Y1 – Y1’, FIG. 8 is a cross-sectional view taken along Y2 – Y2’, and FIG. 9 is a cross-sectional view of taken along X1 - X1’. The cross section Y1 – Y1’ is a vertical cross section through the gates 131a and 131b of the first transistors 11a and 11b, the cross section Y2 – Y2’ is a vertical cross section through the first semiconductor layers 111a and 111b of the first transistors 11a and 11b, and the cross section X1 – X1’ is a vertical cross section along the VVDD 120-2.

In the cross section Y1 – Y1’ of FIG. 7, the gates 131a and 131b are arranged on the front surface 302 of the substrate 3 with the TVDD sidewall 110 interposed therebetween. The gates 131a and 131b overlap the VVDD 120-1 and 120-2 on the back surface 301 of the substrate 3 in plan view.

The gate 131a is commonly used for the first transistor 11a and the second transistor 12a, and has a height substantially the same as the height of at least the second transistor 12a. A channel 119a of a nanosheet for connecting the first semiconductor layer 111a and the second semiconductor layer 112a is formed at a position corresponding to the bottom layer of the gate 131a, and a channel 129a of a nanosheet for connecting the third semiconductor layer 123a and the fourth semiconductor layer 124a is formed at a position corresponding to the top layer.

The gate 131b is commonly used for the first transistor 11b and the second transistor 12b, and has a height substantially the same as the height of at least the second transistor 12b. A channel 119b of a nanosheet for connecting the first semiconductor layer 111b and the second semiconductor layer 112b is formed at a position corresponding to the bottom layer of the gate 131b, and a channel 129b of a nanosheet for connecting the third semiconductor layer 123b and the fourth semiconductor layer 124b is formed at a position corresponding to the top layer.

The gate 131a is further electrically connected to the upper layer wiring 171 by the via plug 61, the upper layer wiring 160-1, and the via plug 71. The gate 131b is electrically connected to the same upper layer wiring 171 by the via plug 62, the upper layer wiring 160-2, and the via plug 72. Thus, the first transistors 11a and 11b forming the switch transistor 40 are connected in parallel.

In the cross section Y2 – Y2’ of FIG. 8, the first semiconductor layer 111a of the first transistor 11a and the first semiconductor layer 111b of the first transistor 11b are arranged on the bottom layer on the front surface 302 side of the substrate 3 with the TVDD sidewall 110 interposed therebetween. The third semiconductor layer 123a of the second transistor 12a is arranged above the first semiconductor layer 111a, and the third semiconductor layer 123b of the second transistor 12b is arranged above the first semiconductor layer 111b.

The first semiconductor layer 111a is connected to the TVDD sidewall 110 by a wiring 245a. The first semiconductor layer 111b is connected to the TVDD sidewall 110 by a wiring 245b on the side opposite to the first semiconductor layer 111a with the TVDD sidewall 110 interposed therebetween.

On the back surface 301 of the substrate 3, the TVDD sidewall 110 is connected to the wiring TVDD BSM2 of the second layer by a via plug 81b, and a power supply voltage is supplied to the first transistors 11a and 11b forming the switch transistor 40.

In the cross section X1 − X1’ of FIG. 9, a VVDD 120-2 extending in the X direction is arranged on the back surface 301 of the substrate 3. The VVDD 120-2 is connected to the wiring VVDD BSM2 of the second layer of the back surface in the Y direction by a via plug 81d. On the front surface 302 of the substrate 3, a first semiconductor layer 111b and a second semiconductor layer 112b are arranged at a position overlapping the VVDD 120-2 in plan view. The second semiconductor layer 112b is connected to the VVDD 120-2 by a through via 431b formed in the substrate 3. The first semiconductor layer 111b is connected to the TVDD sidewall 110 in the depth direction of the plane of the drawing. A gate 131b is arranged between the first semiconductor layer 111b and the second semiconductor layer 112b, and the first semiconductor layer 111b and the second semiconductor layer 112b are connected by a channel 119b formed by a nanosheet.

A third semiconductor layer 123b is provided above the first semiconductor layer 111b, and a fourth semiconductor layer 124b is provided above the second semiconductor layer 112b. A gate 131b is arranged between the third semiconductor layer 123b and the fourth semiconductor layer 124b. The third semiconductor layer 123b and the fourth semiconductor layer 124b are connected by a channel 129b formed by a nanosheet.

The gate 131b is connected to the upper layer wiring 160-2 by a via plug 62, and the upper layer wiring 160-2 is connected to the upper layer wiring 171 by a via plug 72. A control signal output from the control circuit 30 and applied to the gate 131b controls on/off of supply of a power supply voltage from the TVDD sidewall 110 to the VVDD 120-2. When the switch transistor 40 is on, a power supply voltage is supplied from the TVDD sidewall 110 to the VVDD 120-2, and the CFET of the standard cell 10 operates. By turning on/off supply of the power supply voltage from the TVDD sidewall 110 to the VVDD 120-2 by the switch transistor 40, the power supply voltage is supplied to the standard cell 10-2 adjacent in the X direction when necessary, thereby reducing power consumption. The standard cell may be arranged adjacent to the switch transistor 40 in the Y direction, or may not be arranged adjacent to the switch transistor 40.

### First Modified example

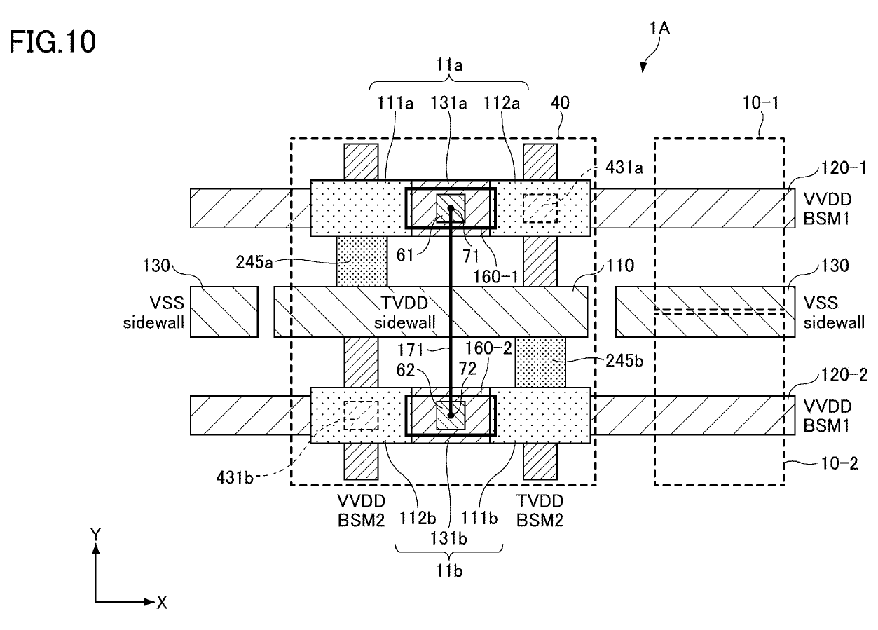

FIG. 10 is a plan view of the bottom layer of the semiconductor device 1A according to the first modified example. In the embodiment described above, the first semiconductor layers 111a and 111b of the plurality of first transistors 11a and 11b forming the switch transistor 40 are connected to the TVDD sidewall 110 at the same position in the X direction. In the first modified example, the first semiconductor layers 111a and 111b are connected to the TVDD sidewall 110 at alternating positions along the X direction.

In the bottom layer of the semiconductor device 1A, a first transistor 11a which overlaps the VVDD 120-1 extending in the X direction in plan view and a first transistor 11b which overlaps the VVDD 120-2 in plan view are arranged. A TVDD sidewall 110 extending in the X direction and a VSS sidewall 130 are arranged between the VVDD 120-1 and 120-2 in plan view. The TVDD sidewall 110 may be arranged in a region where the VSS sidewall 130 is cut off on the same line as the VSS sidewall 130.

In the first transistor 11a provided on one side of the TVDD sidewall 110, a first semiconductor layer 111a, a gate 131a, and a second semiconductor layer 112a are arranged in this order in the X direction, that is, from left to right in the drawing. In the first transistor 11b facing the first transistor 11a with the TVDD sidewall 110 interposed therebetween in the Y direction, the second semiconductor layer 112b, the gate 131b, and the first semiconductor layer 111b are arranged in this order in the X direction, that is, from left to right in the drawing. In the first transistors 11a and 11b, the positions of the source and drain in the X direction are reversed.

The first semiconductor layer 111a overlapping the VVDD 120-1 in plan view is connected to the TVDD sidewall 110 by a wiring 245a. The first semiconductor layer 111b overlapping the VVDD 120-2 in plan view is connected to the TVDD sidewall 110 by a wiring 245b at a position diagonally opposite to the first semiconductor layer 111a. Thus, the wirings 245a and 245b are alternately arranged in the X direction and connected to the TVDD sidewall 110. Further, the through vias 431a and 431b are alternately arranged in the X direction.

Also in the semiconductor device 1A of the first modified example, the power switch circuit 20 is provided adjacent to the standard cells 10-1 and 10-2, so that a plurality of first transistors 11a and 11b of the switch transistor 40 can be efficiently arranged in the vicinity of the TVDD sidewall 110.

### Second Modified Example

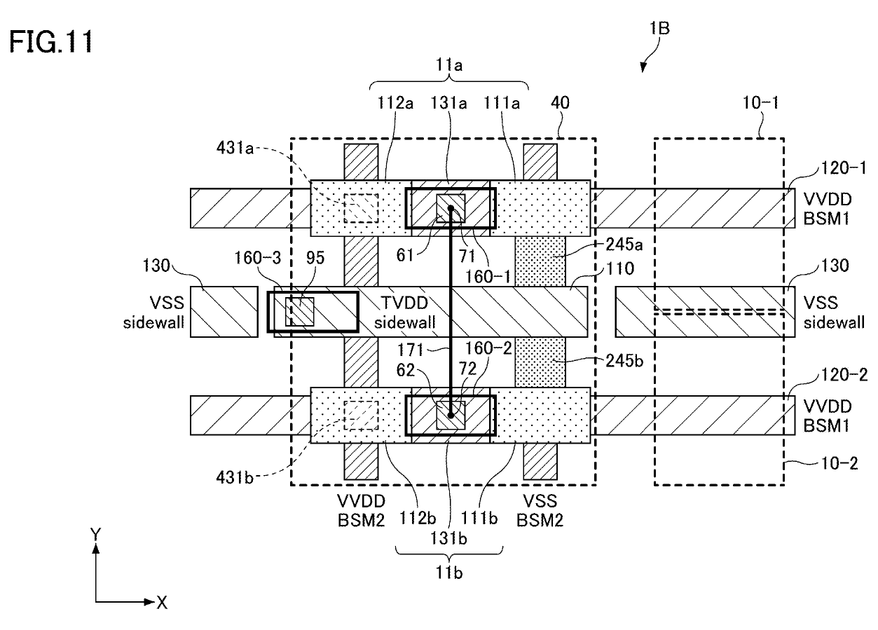

FIG. 11 is a plan view of the bottom layer of the semiconductor device 1B according to a second modified example. In the embodiment described above, a power supply voltage is supplied to the TVDD sidewall 110 from the wiring TVDD BSM2 on the second layer of the back surface 301 of the substrate 3. In the second modified example, a power supply voltage is supplied to the TVDD sidewall 110 from the front surface 302 side of the substrate.

The arrangement relationship of the wiring 245a connecting the TVDD sidewall 110 and the first semiconductor layer 111a overlapping the VVDD 120-1 in plan view, and the wiring 245b connecting the TVDD sidewall 110 and the first semiconductor layer 111b overlapping the VVDD 120-2 in plan view, is the same as that of the embodiment described with reference to FIG. 5. In FIG. 11, in order to clarify the connection relationship between the gates 131a and 131b, the via plug 61 electrically connected to the gate 131a, the upper layer wiring 160-1, and the via plug 71; the via plug 62 electrically connected to the gate 131b, the upper layer wiring 160-2, and the via plug 72; and the further upper layer wiring 171 connecting the via plugs 71 and 72, are illustrated.

In the semiconductor device 1B, the TVDD sidewall 110 is supplied with a power supply voltage from the upper layer wiring 160-3 connected to the via plug 95. The supply of the power supply voltage from the TVDD sidewall 110 to the VVDD 120-1 and 120-2 is controlled by a control signal output from the control circuit 30 to the gates 131a and 131b. When the switch transistor 40 is on, a power supply voltage is supplied from the TVDD sidewall 110 to the VVDD 120-1 and 120-2, and the circuits provided in the standard cells 10-1 and 10-2 operate.

In the configuration illustrated in FIG. 11, the TVDD wiring (TVDD BSM2) of the second layer of the back surface 301 of the substrate 3 can be omitted, and the wiring design of the back surface 301 can be made more flexible.

### Third Modified Example

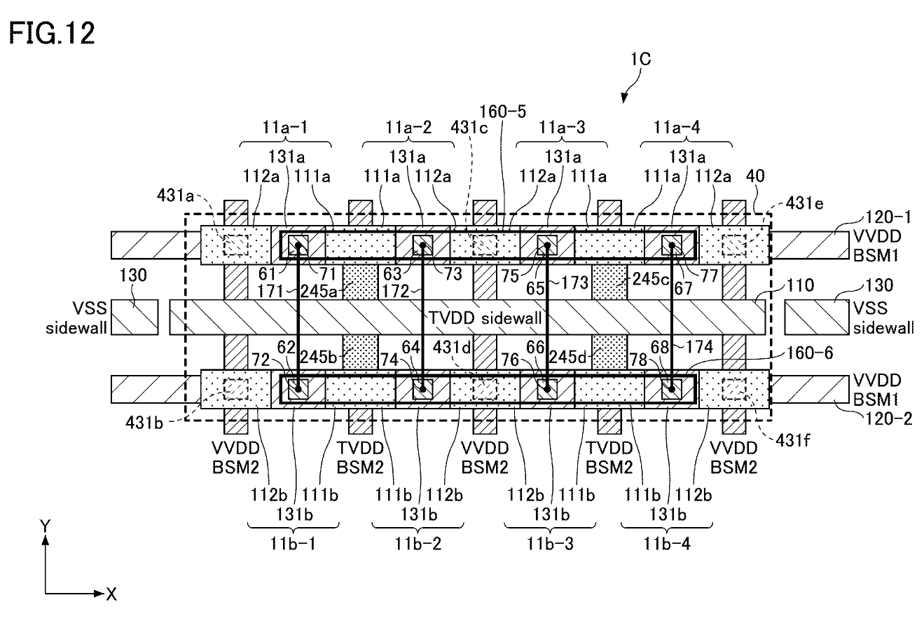

FIG. 12 is a plan view of the bottom layer of the semiconductor device 1C according to a third modified example. In the third modified example, the first transistor 11a is repeatedly arranged in the X direction on one side in the Y direction of the TVDD sidewall 110, and the first transistor 11b is repeatedly arranged in the X direction on the other side.

The first semiconductor layer 111a and the second semiconductor layer 112a are alternately and repeatedly arranged overlapping the VVDD 120-1 extending in the X direction in plan view, and a gate 131a is arranged between the adjacent first semiconductor layer 111a and the second semiconductor layer 112a. Thus, the first transistors 11a-1, 11a-2, 11a-3, and 11a-4 are formed in the X direction. A first semiconductor layer 111a commonly used in the first transistors 11a-1 and 11a-2 is connected to the TVDD sidewall 110 by a wiring 245a. A first semiconductor layer 111a commonly used in the first transistors 11a-3 and 11a-4 is connected to the TVDD sidewall 110 by a wiring 245c. Each gate 131a of the first transistors 11a-1, 11a-2, 11a-3, and 11a-4 is electrically connected to an upper layer wiring 160-5 by via plugs 61, 63, 65, and 67, respectively.

A first semiconductor layer 111b and a second semiconductor layer 112b are alternately and repeatedly arranged so as to overlap VVDD 120-2 extending in the X direction in plan view, and a gate 131b is arranged between the adjacent first semiconductor layer 111b and the second semiconductor layer 112b. Thus, the first transistors 11b-1, 11b-2, 11b-3, and 11b-4 are formed in the X direction. A first semiconductor layer 111b commonly used in the first transistors 11b-1 and 11b-2 is connected to a TVDD sidewall 110 by a wiring 245b. A first semiconductor layer 111b commonly used in the first transistors 11b-3, and 11b-4 is connected to a TVDD sidewall 110 by a wiring 245d. Each gate 131b of the first transistors 11b-1, 11b-2, 11b-3, and 11b-4 is electrically connected to an upper layer wiring 160-6 by via plugs 62, 64, 66, and 68, respectively.

The gate 131a of the first transistor 11a-1 and the gate 131b of the first transistor 11b-1, which face each other in the Y direction with the TVDD sidewall 110 interposed therebetween, are electrically connected by via plugs 61 and 62, upper layer wirings 160-5 and 160-6, via plugs 71 and 72, and a further upper layer wiring 171. The gate 131a of the first transistor 11a-2 and the gate 131b of the first transistor 11b-2 facing each other in the Y direction with the TVDD sidewall 110 interposed therebetween, are electrically connected by via plugs 63 and 64, upper layer wirings 160-5 and 160-6, via plugs 73 and 74, and a further upper layer wiring 172. The gate 131a of the first transistor 11a-3 and the gate 131b of the first transistor 11b-3 facing each other in the Y direction with the TVDD sidewall 110 interposed therebetween, are electrically connected by via plugs 65 and 66, upper layer wirings 160-5 and 160-6, via plugs 75 and 76, and a further upper layer wiring 173. The gate 131a of the first transistor 11a-4 and the gate 131b of the first transistor 11b-4 facing each other in the Y direction with the TVDD sidewall 110 interposed therebetween, are electrically connected by via plugs 67 and 68, upper layer wirings 160-5 and 160-6, via plugs 77 and 78, and a further upper layer wiring 174. In FIG. 12, the wirings electrically connecting the upper layer wiring 160-5 and the upper layer wiring 160-6 are four wirings of the upper layer wirings 171, 172, 173, and 174, but the wiring is not limited to four wirings, and may be one wiring, for example.

In the configuration of FIG. 12, the wiring width and/or pitch in the X direction of the second layer (BSM2) of the back surface 301 of the substrate 3 may be made larger than those of FIG. 10. In this case, a part of the second layer TVDD wiring (TVDD BSM2) of the back surface may be overlapped with the TVDD sidewall 110 in plan view and connected by a via plug (not illustrated).

According to the third modified example, a plurality of first transistors 11a-1 to 11a-4 and 11b-1 to 11b-4 are arranged in the vicinity of the TVDD sidewall, and the scale of the switch transistor 40 is increased to allow a large current to flow.

A semiconductor device having a power switch circuit efficiently laid out in a configuration in which power is supplied by a power wall, is implemented.

Although the configuration of the semiconductor device has been described based on specific configuration examples, the present disclosure is not limited to the configuration examples described above. Embodiments and the first to third modified examples may be combined. For example, in the embodiment, the first modified example, and the third modified example, the operating voltage to be supplied to the TVDD sidewall 110 may be supplied from the wiring of the upper layer. In the third modified example, the wiring 245a to 245d for connecting the first semiconductor layers 111a and 111b of the plurality of first transistors to the TVDD sidewall 110 may be alternately arranged in the X direction. According to the configurations of the embodiments and modified examples, an efficient layout of the power switch circuit 20, especially the switch transistor 40, when the CFET is located in the vicinity of the TVDD sidewall (or power wall) is realized.

What is claimed is:

1. A semiconductor device comprising:
a substrate;
a first power supply line extending in a first direction in plan view on a first surface of the substrate;
a first semiconductor layer and a second semiconductor layer provided on a second surface of the substrate opposite to the first surface and arranged side by side in the first direction overlapping the first power supply line in plan view;
a first through via formed in the substrate and connecting the first power supply line and the second semiconductor layer;
a third semiconductor layer formed above the first semiconductor layer;
a fourth semiconductor layer formed above the second semiconductor layer;
a first gate formed between the first semiconductor layer and the second semiconductor layer and between the third semiconductor layer and the fourth semiconductor layer;
a first transistor having the first semiconductor layer, the second semiconductor layer, and the first gate;
a first conductive wall and a second conductive wall shifted in a second direction different from the first direction from the first power supply line in plan view, and extending in the first direction on the second surface; and
a first wiring connecting the first conductive wall and the first semiconductor layer.

2. The semiconductor device according to claim 1, wherein the first conductive wall and the second conductive wall are arranged at an interval from each other in the first direction.

3. The semiconductor device according to claim 2, wherein the first conductive wall is arranged between two of the second conductive walls in the first direction.

4. The semiconductor device according to claim 1, wherein two of the first transistors are arranged in the second direction with the first conductive wall interposed therebetween, and the first gates of two of the first transistors are electrically connected to each other.

5. The semiconductor device according to claim 1, wherein two of the first transistors are arranged in the second direction with the first conductive wall interposed therebetween, and the first wirings of two of the first transistors are alternately arranged in the first direction.

6. The semiconductor device according to claim 1, wherein two of the first transistors are arranged in the second direction with the first conductive wall interposed therebetween, and the first wirings of two of the first transistors are connected to the first conductive wall at a same position in the first direction.

7. The semiconductor device according to claim 5, wherein a plurality of the first semiconductor layers and a plurality of the second semiconductor layers are alternately arranged in the first direction, and a plurality of the first transistors are connected in parallel.

8. The semiconductor device according to claim 1, wherein
a plurality of the first transistors are provided by alternately arranging a plurality of the first semiconductor layers and a plurality of the second semiconductor layers overlapping with the first power supply line in plan view in the first direction, and
the plurality of the first semiconductor layers are connected to the first conductive wall by a plurality of the first wirings.

9. The semiconductor device according to claim 1, wherein the first conductive wall and the second conductive wall have a height that is greater than or equal to a height of the third semiconductor layer and the fourth semiconductor layer.

10. The semiconductor device according to claim 1, wherein the third semiconductor layer and the fourth semiconductor layer are electrically connected to the second conductive wall.
